(19) United States
(12) Patent Application Publication
(10) Pub. No.: US 2025/0154651 A1
(43) Pub. Date: May 15, 2025

(54) METHOD OF FORMING THIN FILM USING ORGANOMETALLIC COMPOUND AND THIN FILM FORMED THEREBY

(71) Applicants: HANSOL CHEMICAL CO., LTD, Seoul (KR); INDUSTRY-ACADEMIC COOPERATION FOUNDATION, YONSEI UNIVERSITY, Seoul (KR)

(72) Inventors: Jeong-Do OH, Jeollabuk-do (KR); Hyun-kyung LEE, Jeollabuk-do (KR); Mi-Ra PARK, Jeollabuk-do (KR); Jang-Hyeon SEOK, Sejong (KR); Jung-Woo PARK, Seoul (KR); Hyung-Jun KIM, Seoul (KR); Seung-Min CHUNG, Seoul (KR); Seon-Yeong PARK, Gyeonggi-do (KR); Seung-Gyu NA, Seoul (KR)

(21) Appl. No.: 18/039,103

(22) PCT Filed: Nov. 17, 2022
(86) PCT No.: PCT/KR2022/018232

§ 371 Date: Oct. 14, 2024

(30) Foreign Application Priority Data
Nov. 18, 2021 (KR) 10-2021-0159545

(51) Int. Cl. C23C 16/455; C01B 33/20; C23C 16/40; C23C 16/44

(52) U.S. Cl. CPC C23C 16/45553; C01B 33/20; C23C 16/40; C23C 16/4408; C01P 2006/40; C01P 2006/80

(57) ABSTRACT

The present disclosure relates to a method of forming a thin film having excellent properties by depositing an organometallic compound (particularly, an organometallic compound containing rare earth metals) and to a thin film formed thereby.

### TECHNICAL FIELD

The present disclosure relates to a method of forming a thin film using an organometallic compound, and specifically, to a method of forming a thin film with excellent properties using atomic layer deposition (ALD) and a thin film with excellent properties.

### BACKGROUND ART

Recently, with densely packed semiconductor devices and a reduction in channel length, silicon oxide (SiO₂), used as dielectrics, has been replaced with metal gate/high-k transistors.

In particular, due to the line width miniaturization between devices, there is a growing demand for developing high-dielectric constant materials and processes for applying the materials.

On the other hand, high-k materials are required to have a wide band gap, a large band offset, a high k value, good stability on a silicon phase, a minimal SiO₂ interfacial layer, and a high-quality interface on a substrate. In addition, amorphous or highly crystalline films are preferable.

Representative high-k materials being actively researched and applied to replace silicon oxide include hafnium oxide (HfO₂) and the like. There is a consistent demand for next-generation high-k materials, especially in sub-10 nm processes, and rare-earth doped hafnium oxide and the like are brought up as strong candidates for next-generation high-k materials.

In particular, materials containing rare earth elements are promising high-k materials for advanced silicon CMOS, germanium CMOS, and III-V transistor devices, and new-generation oxides based on these materials have been reported to offer significant advantages in capacity compared to typical dielectric materials.

In addition, materials containing rare earth elements are expected to be applied to the fabrication of perovskite materials having properties such as ferroelectricity, pyroelectricity, piezoelectricity, resistance conversion, and the like. In other words, research is in progress for use in various industrial fields, such as fuel cells, sensors, secondary batteries, and the like, by fabricating perovskite in the form of ABO₃ through vapor deposition processes using an organometallic compound precursor, controlling types or compositions of A and B cations (rare earth or transition metals), and providing various properties, such as dielectric properties, electronic conductivity, oxygen ionic conductivity, and the like.

In addition, materials containing rare earth elements are being actively researched for use in encapsulation materials utilizing excellent resistance to water permeation due to a multilayer oxide thin film structure or implementation of next-generation non-volatile memories.

However, the deposition of layers containing rare earth is still difficult, so research has been conducted on rare earth precursors containing various ligands advantageous for deposition and efficient deposition methods of the rare earth precursors.

Even though representative examples of ligands constituting rare earth precursors include a group of compounds such as amide, amidinate, β-diketonate, cyclopentadienyl (Cp), and the like, such precursors have disadvantages that are difficult to be applied to actual processes due to high melting points, low deposition temperatures, high impurities in thin films, relatively low reactivity, and the like. In addition, the development of suitable deposition methods for these precursors has not proceeded smoothly.

As a result, there is a need to develop deposition processes to which improved rare earth precursors are applied so that films containing rare earth can be deposited.

### DOCUMENT OF RELATED ART

### Patent Document

(Patent Document 1) U.S. Pat. No. 8,871,304

### DISCLOSURE

### Technical Problem

Hence, an objective of the present disclosure is to provide an efficient method of forming a thin film using a rare earth organometallic precursor compound and a thin film having excellent properties formed thereby.

However, the problems to be solved by the present disclosure are not limited to the above description, and other problems can be clearly understood by those skilled in the art from the following description.

### Technical Solution

One aspect of the present disclosure provides a thin film formation method of depositing a thin film on a substrate by repeatedly performing a cycle including:
primarily injecting an organometallic precursor compound into a chamber;
primarily purging the organometallic precursor compound from the chamber;
secondarily injecting a reactive gas into the chamber, and
secondarily purging a by-product produced by a reaction with the organometallic precursor compound or residues remaining without reacting with the organometallic precursor compound, from the chamber,
in which the organometallic precursor compound includes a precursor represented by Formula 1.

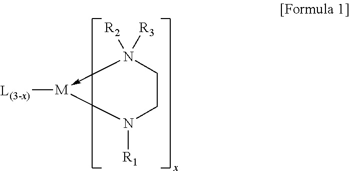

In Formula 1,
M is any one of scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu),
L is N(SiR₄R₅)₂
R₁ to R₅ are each independently hydrogen, or a straight-chain or branched-chain hydrocarbon having 1 to 4 carbon atoms, and
x is an integer in a range of 1 to 3.

Another aspect of the present disclosure provides a thin film
formed by the above formation method and
containing carbon atoms in an amount of 1.5 atomic % or less.

### Advantageous Effects

A method of forming a thin film, according to the present disclosure, has an effect of efficiently forming a thin film having excellent properties.

In particular, the thin film has high thickness uniformity and low amount of impurities, and exhibits excellent electrical characteristics (such as dielectric constant, leakage current, and the like).

In addition, the thin film with excellent properties, formed by the thin film formation method according to the present disclosure, can be used for dielectrics of various electronic devices (especially High K/metal gates, DRAM capacitors), perovskite materials, displays, next-generation memories, and the like.

### DESCRIPTION OF DRAWINGS

FIG. 1 is a diagram of a graph showing changes in growth rate per cycle and deposition thickness uniformity of a thin film according to changes in canister temperature;

FIG. 2 is a diagram of a graph showing changes in growth rate per cycle and deposition thickness uniformity of a thin film according to changes in process temperature;

FIG. 3 is a diagram of a graph showing an analysis of changes in components in a thin film according to changes in process temperature; and

FIG. 4 is a diagram of graphs showing an analysis of the electrical properties of a thin film according to changes in process temperature.

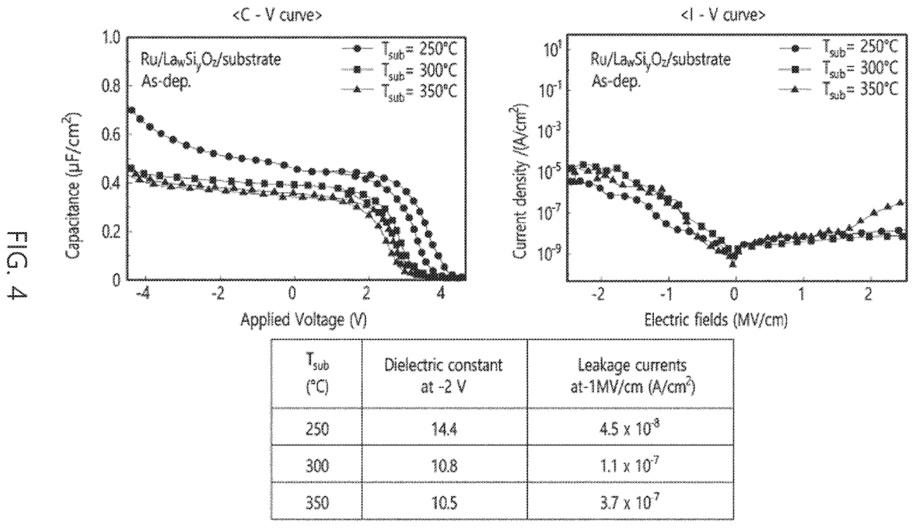

### BEST MODE

Hereinafter, the action and effect of the present disclosure will be described in detail through specific embodiments of the disclosure. However, these embodiments are provided only for illustrative purposes, and the scope of the present disclosure is not limited to the following embodiments.

All terms or words used in the specification and claims have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Thus, the embodiments described in the specification and the configurations illustrated in the drawings are merely examples and do not exhaustively present the technical spirit of the present disclosure. Accordingly, it should be appreciated that there may be various equivalents and modifications that can replace the embodiments and the configurations at the time at which the present application is filed.

As used herein, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, or combinations of them but do not preclude the presence or addition of one or more other features, integers, steps, operations, elements, components, or combinations thereof.

In a thin film formation method according to one aspect of the present disclosure, a thin film is deposited on a substrate by repeatedly performing a cycle including: primarily injecting an organometallic precursor compound into a chamber;
primarily purging the organometallic precursor compound from the chamber;
secondarily injecting a reactive gas into the chamber; and
secondarily purging a by-product produced by a reaction with the organometallic precursor compound and residues remaining without reacting with the organometallic precursor compound, from the chamber,
in which the organometallic precursor compound may include a precursor represented by Formula 1.

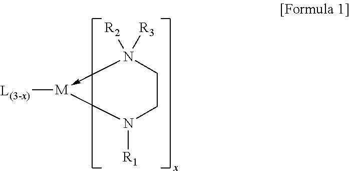

In Formula 1,
M is any one of scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu),
L is N(SiR₄R₅)₂
R₁ to R₅ are each independently hydrogen, or a straight-chain or branched-chain hydrocarbon having 1 to 4 carbon atoms, and
x is an integer in a range of 1 to 3.

The organometallic precursor compound of Formula 1 contains both rare earth and silicon atoms. Thus, it is possible to reduce the difficulties in existing thin film formation methods where a rare earth organometallic precursor compound and a silicon organometallic precursor are separately prepared and then deposited to form a thin film containing both rare earth and silicon atoms.

In addition, existing formation methods typically have difficulty in maintaining a uniform composition in a structure with a high aspect ratio due to differences in volatility and decomposition temperature between the two precursors. However, in the case of using the precursor of the present disclosure, this difficulty can be reduced.

In one embodiment, L in Formula 1 may be bis(trimethylsilyl)amine (BTSA).

On the other hand, the thin film formation method may be an atomic layer deposition (ALD) method, a plasma-enhanced atomic layer deposition (PE-ALD) method among the atomic layer deposition methods, but is not limited thereto.

In addition, in the injecting of the organometallic precursor compound into the chamber, physical adsorption, chemical adsorption, or physical and chemical adsorption may be included.

In one embodiment, the thin film formation method may further include injecting at least one compound selected from among an oxygen (O) atom-containing compound, a nitrogen (N) atom-containing compound, a carbon (C) atom-containing compound, and a silicon (Si) atom-containing compound as the reaction gas.

In one embodiment, the reaction gas may be at least one selected from among oxygen (O₂), ozone (O₃), water (H₂O), hydrogen peroxide (H₂O₂), nitrogen (N₂), ammonia (NH₃), and hydrazine (N₂H₄).

That is, when the desired rare earth-containing film contains oxygen, the reaction gas may be selected from oxygen (O₂), ozone (O₃), water (H₂O), hydrogen peroxide (H₂O₂), and any combination thereof, but is not limited thereto.

When the desired rare earth-containing film contains nitrogen, the reaction gas may be selected from nitrogen (N₂), ammonia (NH₃) hydrazine (N₂H₄), and any combination thereof, but is not limited thereto.

In addition, when the desired rare-earth-containing film contains other metals, the reaction gas may contain other metal atoms.

In one embodiment, a canister temperature of the organometallic precursor compound may be 150° C. or higher.

A canister is used to supply source gas into a reaction chamber in thin film formation methods. Typically, the canister vaporizes an organometallic precursor compound to produce source gas, and then supplies the source gas into the chamber.

When the canister temperature is lower than 150° C., the thickness uniformity of the thin film, formed by the thin film formation method, may be significantly reduced.

This is because, at a canister temperature of lower than 150° C., the supplied amount of the organometallic precursor compound into the chamber is insufficient.

In one embodiment, a process temperature for the deposition may be 350° C. or lower.

As the process temperature increases, the growth rate per cycle may increase. In addition, the thin film formed at a process temperature in a range of 250° C. to 350° C. has excellent uniformity and thus can be used for various purposes.

Furthermore, as the process temperature increases, the amount of carbon atoms, corresponding to an impurity in the thin film being formed, may slightly increase. Even though the dielectric constant may slightly decrease while the leakage current slightly increases, the thin film formed at a process temperature in a range of 250° C. to 350° C. may have properties considered to fall within the scope of excellent quality and thus can be used for various purposes.

In one embodiment, an injection time of the organometallic precursor compound may be in a range of 1 second or more and 30 seconds or less, and an injection amount of carrier gas of the organometallic precursor compound may be in a range of 10 sccm or more and 5000 sccm or less.

In addition, an injection time of the reaction gas may be in a range of 1 second or more and 30 seconds or less, an injection amount of the reaction gas may be in a range of 10 sccm or more and 5000 sccm or less, and a concentration of the reaction gas may be in a range of 50 g/m³ or more and 500 g/m³ or less.

In one embodiment, purge gas injection times in the primarily purging and the secondarily purging are independently in a range of 1 second or more and 3 minutes or less. In addition, purge gas injection amounts in the primarily purging and the secondarily purging may be each independently in a range of 10 sccm or more and 5000 sccm or less.

When the above-described process conditions for the organometallic precursor compound, the reaction gas, and the purge gas are not satisfied, a thin film having excellent properties is unobtainable.

On the other hand, the cycle of the method of forming the thin film may be performed 1 time or more and 100,000 times or less.

A thin film, according to another aspect of the present disclosure, is formed by the above formation method, and may contain carbon (C) atoms as an impurity in an amount of 1.5 atomic % or less.

In addition, nitrogen (N) atoms, another impurity in the thin film, may not be detected by X-ray photoelectron spectroscopy (XPS).

In one embodiment, the thin film may have a dielectric constant of 10 or more and a leakage current of 4.0×10⁻⁷ A/cm² or less.

### MODE FOR INVENTION

Hereinafter, the present disclosure will be described in more detail using examples, but is not limited thereto.

### [Synthesis Example]

[Preparation of NH^{t}BuCH₂CH₂NMe₂ Ligand]

1 eq of 2-Chloro-N,N-dimethylethylamine hydrochloride was slowly dissolved in 100 mL of water, followed by slowly adding 1 eq of a NaOH aqueous solution at a temperature of 0° C. Next, 4 eq of t-butylamine was slowly added with a dropping funnel at the same temperature, and the mixture was stirred overnight at room temperature. After completion of the reaction, 1 eq of NaOH was added, the mixture was further stirred, and extraction was performed with a hexane solvent. Water was removed from an organic layer with MgSO₄, and solvent removal and purification were then performed under normal pressure. The synthesized NH^{t}BuCH₂CH₂NMe₂ was a colorless liquid, and the synthesis yield was 30%.

The chemical structural formula and NMR measurement results of the obtained NH^{t}BuCH₂CH₂NMe₂ are as follows.

[Chemical Structural Formula of NH^{t}BuCH₂CH₂NMe₂]

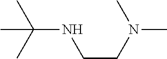

¹H-NMR (400 MHz, Benzene-D6):

δ 1.06 (s, 9H), 2.06 (s, 6H), 2.33 (t, 2H), 2.56 (t, 2H)

[Preparation of La(btsa)₂(NH^{t}BuCH₂CH₂NMe₂)(La(N(SiMe₃)₂)₂(NH^{t}BuCH₂CH₂NMe₂))]

Toluene, serving as a solvent, was added to a flask containing 1 eq of La(btsa)₃, and 1 eq of NH^{t}BuCH₂CH₂NMe₂ prepared in Synthesis Example was added. The mixture was heated overnight at a temperature of 70° C. After completion of the reaction, La(btsa)₂(NH^{t}BuCH₂CH₂NMe₂) is obtained by concentration under reduced pressure and sublimation purification at a temperature of 110° C. at a pressure of 56 mTorr.

The synthesized La(btsa)₂(NH^{t}BuCH₂CH₂NMe₂) was an ivory solid, and the synthesis yield was 76%.

The chemical structural formula and NMR measurement results of the synthesized La(btsa)₂(NH^{t}BuCH₂CH₂NMe₂) are as follows.

[Chemical Structural Formula of La(Btsa)₂(NH^{t}BuCH₂CH₂NMe₂)]

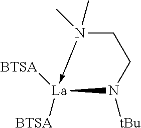

In the chemical structural formula of La(btsa)₂(NH^{t}BuCH₂CH₂NMe₂), BTSA indicates a bis(trimethylsilyl)amine group and tBu indicates a tert-butyl group.

¹H-NMR (400 MHz, THF-d8):

δ 0.15 (s, 36H), 1.23 (s, 9H), 2.48 (s, 6H), 3.03 (t, 2H), 3.09 (t, 2H)

### [Preparation Example]

The organometallic precursor compound prepared in the Synthesis Example was deposited on a thin film using atomic layer deposition (ALD) equipment.

The substrate used in this experiment is a p-type Si (100) wafer, which has a resistance of 0.02 Ω·m. Before deposition, the p-type Si wafer was cleaned in acetone, ethanol, and DI water by ultrasound application for 10 minutes each. The native oxide thin film on the Si wafer was immersed in a 10% HF solution (HF:H₂O=1:9) for 10 seconds and then removed. The HF-cleaned Si wafer was immediately transferred to an atomic layer deposition (ALD) chamber. La(btsa)₂(NH^{t}BuCH₂CH₂NMe₂), an organometallic precursor compound used in this experiment, was a precursor containing both a La atom, rare earth metal, and a Si atom, in which a canister temperature was maintained at a range of 130° C. to 160° C.

La(btsa)₂(NH^{t}BuCH₂CH₂NMe₂) (10 seconds), Ar (30 seconds), ozone (O₃) (10 seconds), and Ar (30 seconds) were sequentially supplied.

Ozone (O₃) used as a reaction gas was injected at a flow rate of 1,000 sccm by turning the power of a pneumatic valve on and off. At this time, ozone had a concentration of 220 g/m³.

The argon (Ar) used for purging La(btsa)₂(NH^{t}BuCH₂CH₂NMe₂) and ozone was injected at a flow rate of 1,500 sccm.

In a process temperature range of 250° C. to 350° C., a reactor pressure was 1 Torr, and a cycle was performed 200 times.

Table 1 shows process conditions for thin film formation.

TABLE 1

| | | | Injection | | | | | | | |
|---|---|---|---|---|---|---|---|---|---|---|
| | | | amount of | | | | Injection | Injection | | |
| | | Injection | precursor- | Injection | | Injection | time of | amount of | | |
| Canister | Process | time of | carrying | time of | Concentration | amount of | Argon for | Argon for | ALD | Process |
| temperature | temperature | Precursor | Argon | Ozone | of Ozone | Ozone | purging | purging | Cycle | pressure |
| (° C.) | (° C.) | (s) | (sccm) | (s) | (g/m³) | (sccm) | (s) | (sccm) | (number) | (Torr) |
| 130 to | 250 to | 10 | 500 | 10 | 220 | 1000 | 30/30* | 1500 | 200 | 1 |
| 160 | 350 | | | | | | | | | |

*(purging after injecting precursor/purging after injecting ozone) time

The growth rate per cycle, thickness uniformity, components, and composition ratios of the thin film formed by Preparation Example were analyzed.

### (1) Measurement of Growth Rate Per Cycle

The growth rate per cycle was calculated by Equation 1.

$$Growth rate per cycle ( Å / cycle ) = deposition thickness / ALD cycle \qquad [ Equation 1 ]$$

The deposition thickness in Equation 1 was measured using an ellipsometer and confirmed using FE-SEM.

### (2) Measurement of Thickness Uniformity

The thickness uniformity was calculated by Equation 2.

$$Thickness uniformity ( \% ) = ( maximum thickness - minimum thickn ess ) \text{} / ( 2 \times average thickness ) \qquad [ Equation 2 ]$$

The maximum, minimum, and average thicknesses in Equation 2 were determined by values measured at nine locations on the wafer where the thin film was formed.

The thicknesses were measured using an ellipsometer (manufacturer: Ellipso Technology, model name: Elli-SE-UaM8), and the nine locations on the wafer were center (C), right (R), left (L), top (T), bottom (B), top right (RT), top left (LT), bottom right (RB) and bottom left (LB).

### (3) Measurement of Components and Composition Ratios

The components and composition ratios of the thin film being formed were analyzed using X-ray photoelectron spectroscopy (XPS).

### Example 1

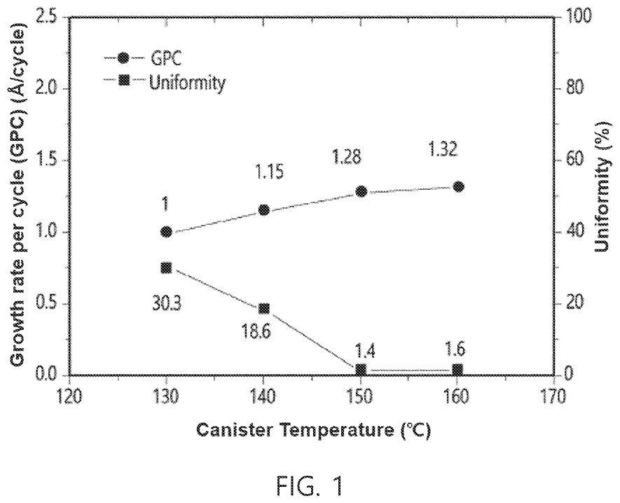

Of all the process conditions described in Table 1, a process temperature was fixed at 250° C. Then, a thin film was formed according to Preparation Example by varying canister temperatures in a range of 130° C. to 160° C., and the growth rate per cycle (GPC) and thickness uniformity of the thin film were measured. The results thereof are shown in FIG. 1.

As shown in FIG. 1, the higher the canister temperature, the higher the growth rate per cycle and the lower the thickness uniformity.

When the canister temperatures were at 130° C. and 140° C., thickness deviations depending on the measurement locations of the thin film were extremely high at 30.3% and 18.6%, respectively, confirming that the thin film was not uniform.

On the contrary, when the canister temperatures were raised to 150° C. and 160° C., thickness deviations depending on the measurement locations of the thin film were extremely low at 1.4% and 1.6%, respectively, confirming that the thin film with a sufficiently uniform thickness was formed.

In other words, it was seen that the canister temperature significantly affected the growth rate per cycle and thickness uniformity of the thin film.

### Example 2

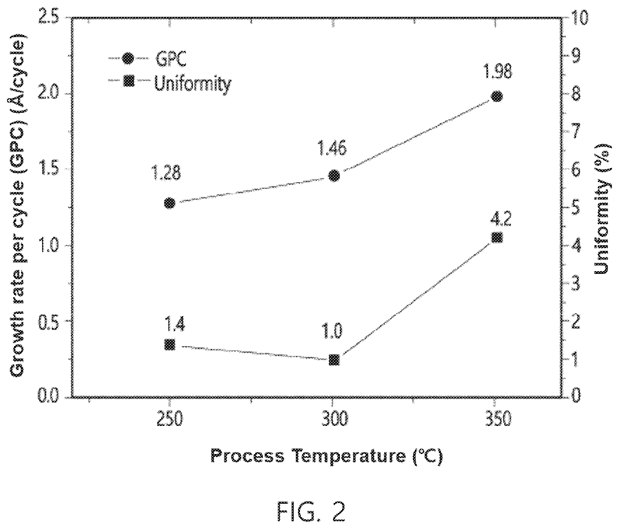

Of all the process conditions described in Table 1, a canister temperature was fixed at 150° C. Then, a thin film was formed according to Preparation Example by varying process temperatures in a range of 250° C. to 350° C., and the growth rate per cycle (GPC) and thickness uniformity of the thin film were measured. The results thereof are shown in FIG. 2.

As shown in FIG. 2, it was confirmed that the higher the process temperature, the higher the growth rate per cycle.

In addition, when the process temperatures were at 250° C., 300° C., and 350° C., thickness deviations depending on the measurement locations of the thin film corresponded to 1.4%, 1.0%, and 4.2%, respectively, confirming that the thickness uniformity of the thin film was excellent.

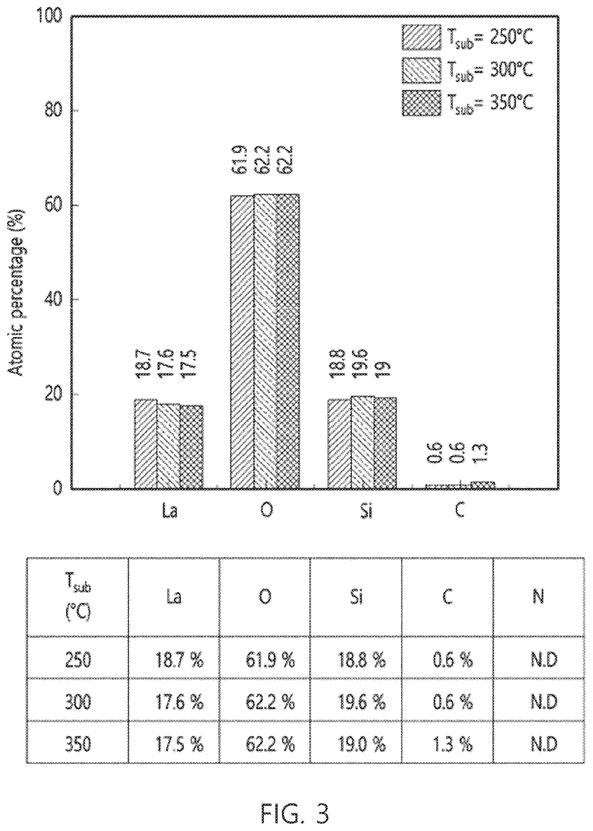

Furthermore, as shown in FIG. 3, elements of the thin film formed according to Example 2, in which the process temperatures varied, were analyzed.

La, Si, and O elements were detected in all thin films, but nitrogen (N), an impurity, was not detected.

Carbon (C), an impurity, on the other hand, was detected in all thin films, and the amount thereof varied depending on the process temperatures.

In other words, the higher the process temperature, the greater the amount of carbon, the impurity in the thin film. However, the thin film formed at a process temperature in the range of 250° C. to 350° C. contained carbon at an amount of 1.3 atomic % or less, exhibiting excellent properties with extremely low carbon amount.

In addition, there was little difference in the ratio of La, Si, and O in the thin film according to the changes in process temperature during formation, and the atomic ratio of La:Si:O was 1:1:3, confirming that the LaSiO₃ thin film was formed.

On the other hand, as a result of measuring the electrical properties (dielectric constant and leakage current) of the formed thin film, it was confirmed that the higher the process temperature during the thin film formation, the lower the measurement value of the dielectric constant, and the higher the measurement value of the leakage current.

All of the measurement values of the dielectric constant and the leakage current of the thin film formed at a process temperature in the range of 250° C. to 350° C. fell within the range suitable enough for practical use.

Through the above thin film formation, it was seen that a thin film with excellent properties was formable by ALD in which various process conditions were controlled.

In particular, it was confirmed that the properties of the thin film were improvable with the adjustment of the canister temperature and the process temperature.

In other words, control of the process conditions enabled the thin film with a uniform thickness to be formed and excellent thin film properties (electrical properties such as dielectric properties and amount of impurities) to be obtained.

The scope of the present disclosure is defined by the following claims rather than the description which is presented above. Furthermore, the present disclosure is intended to cover not only the exemplary embodiments, but also various alternatives, modifications, equivalents, and other embodiments that may be included within the spirit and scope of the present disclosure as defined by the appended claims.

### INDUSTRIAL APPLICABILITY

A thin film formation method, according to the present disclosure, has an effect of efficiently forming a thin film with excellent properties.

In particular, the thin film has high thickness uniformity and low amount of impurities, and exhibits excellent electrical characteristics (such as dielectric constant, leakage current, and the like).

In addition, the thin film with excellent properties, formed by the thin film formation method according to the present disclosure, can be used for dielectrics of various electronic devices (especially High K/metal gates, DRAM capacitors), perovskite materials, displays, next-generation memories, and the like.

1. A thin film formation method of depositing a thin film on a substrate by repeatedly performing a cycle comprising:
primarily injecting an organometallic precursor compound into a chamber;
primarily purging the organometallic precursor compound from the chamber;
secondarily injecting a reactive gas into the chamber; and
secondarily purging a by-product produced by a reaction with the organometallic precursor compound and residues remaining without reacting with the organometallic precursor compound, from the chamber,
wherein the organometallic precursor compound comprises a precursor represented by Formula 1, 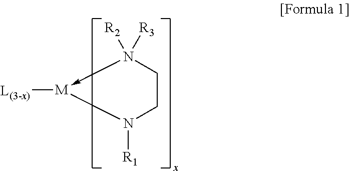
wherein in Formula 1, M is any one of scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu),
L is N(SiR₄R₅)₂
R₁ to R₅ are each independently hydrogen, or a straight-chain or branched-chain hydrocarbon having 1 to 4 carbon atoms, and
x is an integer in a range of 1 to 3.

2. The method of claim 1, wherein L in Formula 1 is a bis(trimethylsilyl)amine group.

3. The method of claim 1, wherein the reaction gas is at least one selected from the group consisting of ozone (O₃) and water (H₂O).

4. The method of claim 1, wherein a canister temperature of the organometallic precursor compound is 150° C. or higher.

5. The method of claim 1, wherein a process temperature is 350° C. or lower.

6. The method of claim 1, wherein an injection time of the organometallic precursor compound is in a range of 1 second or more and 30 seconds or less,
an injection amount of a carrier gas for the organometallic precursor compound is in a range of 10 sccm or more and 5000 sccm or less,
an injection time of the reaction gas is in a range of 1 second or more and 30 seconds or less,
an injection amount of the reaction gas is in a range of 10 sccm or more and 5000 sccm or less, and
a concentration of the reaction gas is in a range of 50 g/m³ or more and 500 g/m³ or less.

7. The method of claim 1, wherein purge gas injection times in the primarily purging and the secondarily purging are each independently in a range of 1 second or more and 3 minutes or less, and
purge gas injection amounts in the primarily purging and the secondarily purging are each independently in a range of 10 sccm or more and 5000 sccm or less.

8. A thin film formed by the method of any one of claims 1 to 7, the thin film comprising carbon atoms in an amount of 1.5 atomic % or less.

9. The thin film of claim 8, wherein a dielectric constant is 10 or more, and a leakage current is 4.0×10⁻⁷ A/cm² or less.
